(19) United States
(12) Patent Application Publication
(10) Pub. No.: US 2021/0010148 A1
(43) Pub. Date: Jan. 14, 2021

(54) SUBSTRATE PROCESSING SYSTEM AND SUBSTRATE PROCESSING METHOD

(71) Applicant: SCREEN HOLDINGS CO., LTD., Kyoto (JP)

(72) Inventor: Hisashi NISHIKIUCHI, Kyoto (JP)

(21) Appl. No.: 15/999,054

(22) PCT Filed: Oct. 25, 2016
(86) PCT No.: PCT/JP2016/081538

§ 371 Date: Aug. 17, 2018

(30) Foreign Application Priority Data
Feb. 19, 2016 (JP) 2016-029467

(51) Int. Cl. C25D 17/06; B08B 3/04; B08B 1/02; B08B 1/04; B08B 1/00; C25D 7/12; C25D 21/12; H01L 21/67

(52) U.S. Cl. CPC C25D 17/06; B08B 3/041; B08B 1/02; B08B 1/04; H01L 21/67236; C25D 7/12; C25D 21/12; H01L 21/67173; H01L 21/6723; B08B 1/001

(57) ABSTRACT

A substrate processing system comprises: a plating device including a first conveying unit for conveying a first substrate and configured to convey the first substrate by the first conveying unit after a plating process is applied to a surface of the first substrate in a stationary state; and a pre-stage device including a second conveying unit for conveying a second substrate and configured to convey the second substrate as the first substrate to the plating device by the second conveying unit in response to unloading of the first substrate by the first conveying unit. In the system, a timing at which the second conveying unit conveys the second substrate to the plating device being controlled according to a plating process time.

### TECHNICAL FIELD

This invention relates to a substrate processing system and a substrate processing method for applying a plating process to surfaces of various substrates such as semiconductor substrates, glass substrates for photo mask, glass substrates for liquid crystal display, glass substrates for plasma display, substrates for FED (Field Emission Display), substrates for optical disc, substrates for magnetic disc, substrates for magneto-optical disc and wiring substrates (hereinafter, merely referred to as “substrates”).

Contents disclosed in the specification, drawings and claims of the following Japanese Patent Application are all incorporated herein by reference.

Japanese Patent Application No. 2016-29467 (filed on Feb. 19, 2016)

### BACKGROUND

A technique has been proposed which applies a plating process to a surface of a substrate in manufacturing processes of electronic components such as semiconductor devices and liquid crystal display devices, wiring boards for mounting electronic components and the like. For example, in an apparatus described in patent literature 1, a substrate held by a substrate holder is carried in, and the substrate holder is carried out after a series of surface processes including a plating process are applied to a surface of the substrate. Here, to perform the surface processes, process tanks such as a pre-water wash tank, a pre-process tank, a rinse tank, a first plating tank, a rinse tank, a second plating tank, a rinse tank and a blow tank are arranged in the order of processes. A substrate conveying holder conveys the substrate holder successively to each process tank while holding the substrate holder, and the above surface processes are performed by inserting the substrate holder perpendicularly into the process tanks.

### CITATION LIST

### Patent Literature

[Patent literature 1] JP 2015-187306A

### SUMMARY

### Technical Problem

In the above conventional technique, the surface processes cannot be performed for the next substrate until a series of surface processes (loading process, pre-processing process, water washing process, plating process, rinsing process, blowing process and unloading process, etc.) for one substrate are completed. Thus, there has been room for improvement in terms of throughput. As a measure to solve that problem, it is considered to adopt a continuous surface processing method. Specifically, throughput can be improved by continuously conveying a substrate by a conveying mechanism such as a conveyor and performing a series of surface processes in process tanks arranged in the order of the processes along a conveyance path.

However, in this continuous surface processing method, the substrate needs to be conveyed at a constant speed. For example, to change a plating process time, it has been necessary to match process times of the other processes with that of the plating process by changing sizes of the process tanks for performing the other processes. As just described, it is difficult to flexibly cope with a change in the plating process time and versatility lacks.

This invention was developed in view of the above problem and aims to provide a substrate processing system and a substrate processing method capable of performing a plating process with excellent throughput while flexibly coping with a change in plating process time.

### Solution to Problem

One aspect of the invention is a substrate processing system, the system comprising: a plating device including a first conveying unit for conveying a first substrate and configured to convey the first substrate by the first conveying unit after a plating process is applied to a surface of the first substrate in a stationary state; and a pre-stage device including a second conveying unit for conveying a second substrate and configured to convey the second substrate as the first substrate to the plating device by the second conveying unit in response to unloading of the first substrate by the first conveying unit; wherein a timing at which the second conveying unit conveys the second substrate to the plating device being controlled according to a plating process time.

Other aspect of the invention is a substrate processing method, comprising: unloading a first substrate from a plating device after a plating process is applied to a surface of the first substrate in a stationary state by the plating device; and conveying a second substrate as the first substrate to the plating device by a pre-stage device, wherein a timing at which the second substrate is conveyed to the plating device being controlled according to a plating process time.

In the invention thus configured, when the plating process is completed for the substrate (first substrate) in the plating device, the next substrate (second substrate) is conveyed to the plating device while the substrate is carried out. Thus, the plating device is continuously performed and excellent throughput is obtained. Further, even if the plating process time is changed, the timing of conveying the substrate to the plating device is controlled according to the changed time, a change in the plating process time can be flexibility coped with and high versatility is obtained.

### Advantageous Effects of Invention

As described above, according to the invention, not only excellent throughput is obtained by performing the continuous plating process, but also a change in the plating process time can be flexibly coped with by controlling the conveyance timing of the substrate to the plating device and high versatility is obtained.

All of a plurality of constituent elements of each aspect of the invention described above are not essential and some of the plurality of constituent elements can be changed, deleted or replaced by new other constituent elements or limitation contents can be partially deleted as appropriate to solve some or all of the problems described above or achieve some or all of effects described in this specification. Further, some or all of technical features included in one aspect of the invention described above can be combined with some or all of technical features included in another aspect of the invention described above into one independent aspect of the invention to solve some or all of the problems described above or achieve some or all of effects described in this specification.

### BRIEF DESCRIPTION OF DRAWINGS

FIG. 1 is a plan view showing a first embodiment of a substrate processing system according to the invention.

FIG. 2A is a diagram schematically showing the configurations of the first processing device row and the second processing device row.

FIG. 2B is a diagram schematically showing the configuration of the second processing device row.

FIG. 2C is a diagram schematically showing the configurations of the second processing device row and the third processing device row.

FIG. 3 is a block diagram showing an electrical configuration of the substrate processing system.

FIG. 4 is a perspective view schematically showing the configuration of the transfer device.

FIG. 5 is an exploded assembly perspective view schematically showing the configuration of the plating device constituting the first processing device row.

FIG. 6 is a diagram schematically showing lifting and lowering operations of a backup plate with respect to the conveyor rollers in the plating device of FIG. 5.

FIG. 7 is a diagram schematically showing a plating operation by the plating device of FIG. 5.

FIG. 8 is an exploded assembly perspective view schematically showing the configuration of the plating device constituting the third processing device row.

FIG. 9 is a diagram schematically showing a plating operation by the plating device of FIG. 8.

FIG. 10 is a diagram schematically showing the other configuration of the plating device.

FIG. 11 is a diagram schematically showing another configuration of the plating device.

FIG. 12 is a diagram schematically showing then further other configuration of the plating device.

FIG. 13 is a plan view showing a second embodiment of the substrate processing system according to the invention.

FIG. 14 is a plan view showing a third embodiment of the substrate processing system according to the invention.

### DESCRIPTION OF EMBODIMENTS

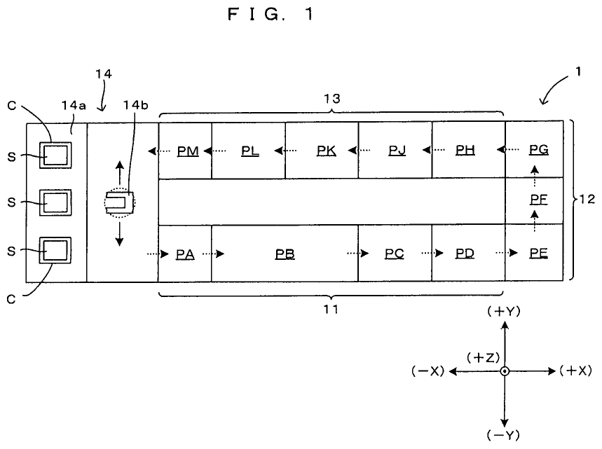

FIG. 1 is a plan view showing a first embodiment of a substrate processing system according to the invention. Note that, to clarify an arrangement relationship of each system component, a horizontal direction from left to right of FIG. 1 is referred to as a “+X direction” and an opposite direction is referred to as a “−X direction” in FIG. 1 and each figure described later. Further, out of horizontal directions perpendicular to the X direction, a direction toward a back side of the substrate processing system 1 is referred to as a “+Y direction” and a direction toward a front side of the substrate processing system 1 is referred to as a “−Y direction”. Furthermore, upward and downward directions along a vertical direction are respectively referred to as a “+Z direction” and “−Z direction”.

As shown in FIG. 1, the substrate processing system 1 includes an indexer device 14, and a first processing device row 11, a second processing device row 12 and a third processing device row 13 coupled to this indexer device 14 into a U shape in a plan view. The first processing device row 11 is configured such that processing units PA to PD are aligned in this order in the (+X) direction and a desired process is performed in each processing device PA to PD while a substrate S received from the indexer device 14 is conveyed in the (+X) direction. Further, the second processing device row 12 is configured such that processing devices PE to PG are aligned in this order in the (+Y) direction and a desired process is performed in each processing device PE to PG while the substrate S received from the first processing device row 11 is conveyed in the (+Y) direction. Further, the third processing device row 13 is configured such that processing devices PH, PJ to PM are aligned in this order in the (−X) direction and a desired process is performed in each processing device PH, PJ to PM while the substrate S received from the second processing device row 12 is conveyed in the (−X) direction. Further, the substrate S reaching the processing device PM is carried out from the third processing device row 13 by the indexer device 14. In this embodiment, a front surface and a back surface of the substrate S respectively correspond to “one principal surface” and an “other principal surface” of the present invention.

The indexer device 14 includes a cassette placing part 14a on which substrate storage cassettes C (hereinafter, referred to as “cassettes C”) storing the substrates S are placed, and a conveyor robot 14b for taking in and out the substrate S into and from the cassette C placed on this placing part 14a. The indexer device 14 successively takes out the substrates S to be plated from the substrate storage cassettes C by the conveyor robot 14b and conveys the taken-out substrates S to the first processing device row 11 (loading). Further, the indexer device 14 returns the substrate S subjected to a series of processes including plating processes from the third process row 13, for example, to the initial cassette C by the conveyor robot 14b (unloading).

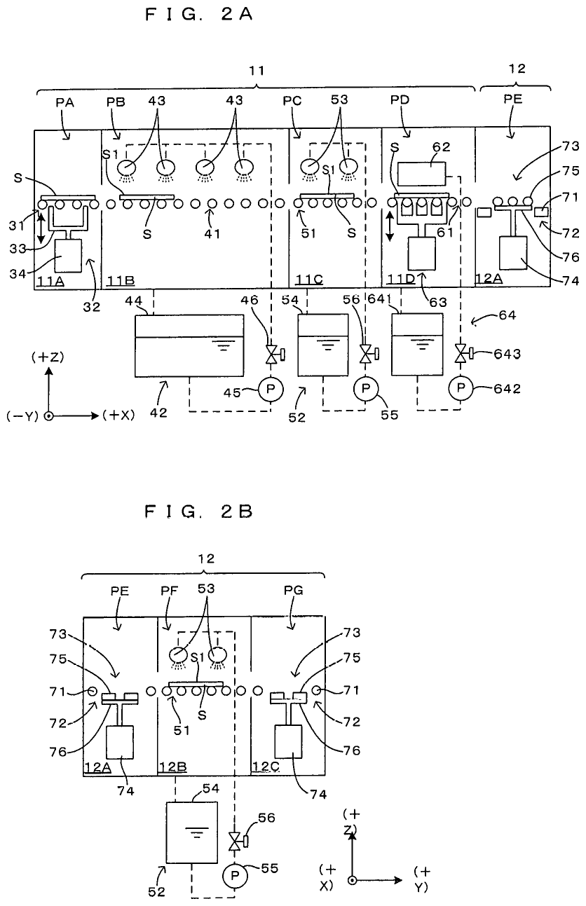

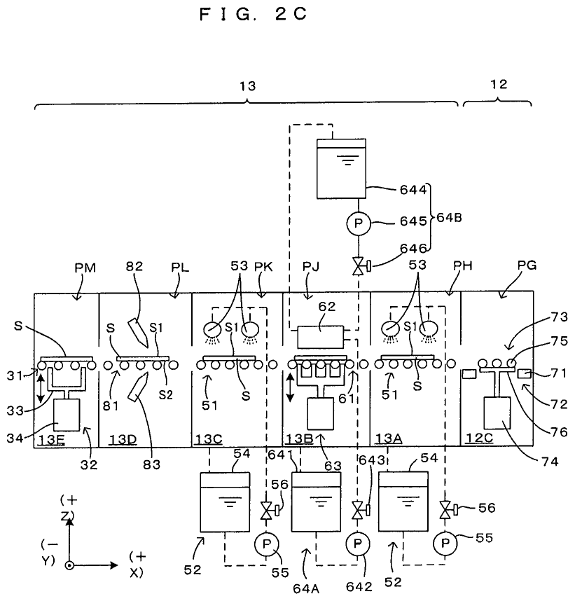

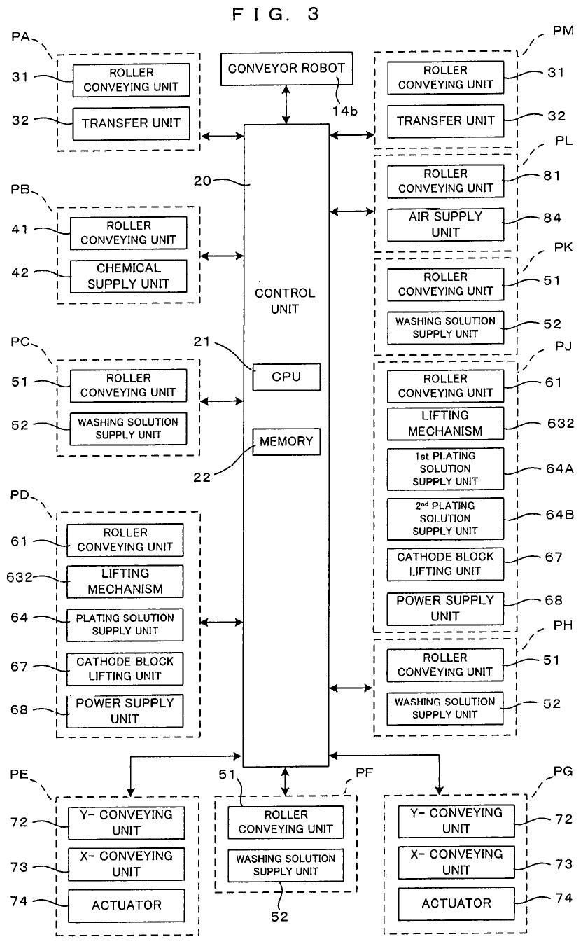

FIG. 2A is a diagram schematically showing the configurations of the first processing device row and the second processing device row, FIG. 2B is a diagram schematically showing the configuration of the second processing device row, and FIG. 2C is a diagram schematically showing the configurations of the second processing device row and the third processing device row. Further, FIG. 3 is a block diagram showing an electrical configuration of the substrate processing system. In the first processing device row 11, a loading chamber 11A, a pre-processing chamber 11B, a water washing chamber 11C and a plating chamber 11D are successively provided from an upstream side (side of the indexer device 14) in a conveying direction (+X) of the substrates S as shown in FIG. 2A.

A receiving device PA for receiving an unprocessed substrate S from the conveyor robot 14b is provided in the loading chamber 11A. This receiving device PA includes a roller conveying unit 31 composed of a plurality of conveyor rollers, and a transfer unit 32 for receiving the unprocessed substrate S from the conveyor robot 14b and transferring the unprocessed substrate S to the roller conveying unit 31. The transfer unit 32 is composed of a plurality of supporting pins 33 and an actuator 34 such as an air cylinder for driving the supporting pins 33 for upward and downward movements between a receiving position where the supporting pins 33 project upwardly of the conveyor rollers and a retracted position retracted downwardly from the conveyor rollers. In response to a lifting command from a control unit 20 for controlling the entire substrate processing system 1, the actuator 34 operates to receive the substrate S in a horizontal posture from the conveyor robot 14b with the supporting pins 33 set at the receiving position. Thereafter, in response to a lowering command from the control unit 20, the actuator 34 operates to displace the supporting pins 33 to the retracted position, thereby transferring the substrate S onto the conveyor rollers. Then, in response to a roller driving command from the control unit 20, the roller conveying unit 31 operates to convey the substrate S to the pre-processing chamber 11B.

A pre-processing device PB for performing a pre-process to remove organic substances and oxides adhering to a front surface S1 of the substrate S before the plating process is applied to the substrate S is provided in the pre-processing chamber 11B. This pre-processing device PB includes a roller conveying unit 41 composed of a plurality of conveyor rollers and a chemical supply unit 42 for supplying a chemical for the pre-process to the front surface S1 of the substrate S being conveyed by the roller conveying unit 41. The chemical supply unit 42 includes a plurality of chemical discharge nozzles 43 arranged above the conveyor rollers, a chemical tank 44, a pump 45 and a valve 46. In response to a pre-process command from the control unit 20, the roller conveying unit 41 operates to convey the substrate S in a horizontal posture in the (+X) direction with the front surface S1 faced up.

Further, in parallel with this horizontal conveyance of the substrate S, the pump 45 operates and the valve 46 is opened to supply the chemical stored in the chemical tank 44 to each chemical discharge nozzle 43 via the pump 45 and the valve 46. Thus, the chemical is discharged from each chemical discharge nozzle 43 toward the front surface S1 of the substrate S being conveyed toward the water washing chamber 11C. In this way, the chemical is supplied to the front surface S1 of the substrate S being conveyed in the (+X) direction, thereby performing the so-called pre-process to remove organic components and oxide components adhering to this front surface S1 before the plating process. Although the chemical after the process in the pre-processing chamber 11B is collected, returned to the chemical tank 44 and reused to reduce running cost in this embodiment, it goes without saying that the chemical may be disposable.

A water washing device PC for performing a water washing process to wash and remove the washing solution from the substrate S subjected to the pre-process using water as a washing solution is provided in the water washing chamber 11C located downstream of the pre-processing device PB. This water washing device PC includes a roller conveying unit 51 composed of a plurality of conveyor rollers and a washing solution supply unit 52 for supplying water (washing solution) to the front surface S1 of the substrate S being conveyed by the roller conveying unit 51. The washing solution supply unit 52 includes a plurality of washing solution discharge nozzles 53 arranged above the conveyor rollers, a washing solution tank 54, a pump 55 and a valve 56. In response to a water washing command from the control unit 20, the roller conveying unit 51 operates to convey the substrate S in a horizontal posture in the (+X) direction with the front surface S1 faced up.

Further, in parallel with this horizontal conveyance of the substrate S, the valve 56 is opened and the pump 55 operates to supply the washing solution stored in the washing solution tank 54 to each washing solution discharge nozzle 53 via the pump 55 and the valve 56 and discharge the washing solution from each washing solution discharge nozzle 53 to the front surface S1 of the substrate S being conveyed toward the plating chamber 11D. In this way, the washing solution is supplied to the front surface S1 of the substrate S being conveyed in the (+X) direction, and the chemical remaining on the substrate S is water-washed and removed before the plating process. Although the washing solution after the process in the water washing chamber 11C is collected, returned to the washing solution tank 54 and reused to reduce running cost in this embodiment, it goes without saying that the washing solution may be disposable. Further, every time the water washing process is performed a fixed number of times, the washing solution may be exchanged. These points also apply to other water washing devices described later.

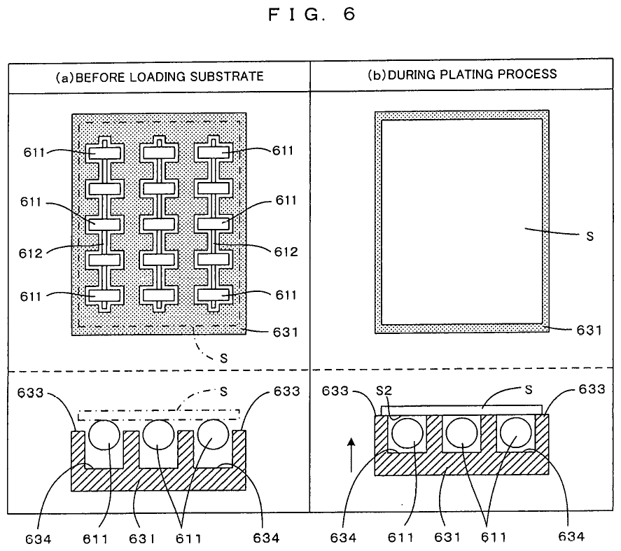

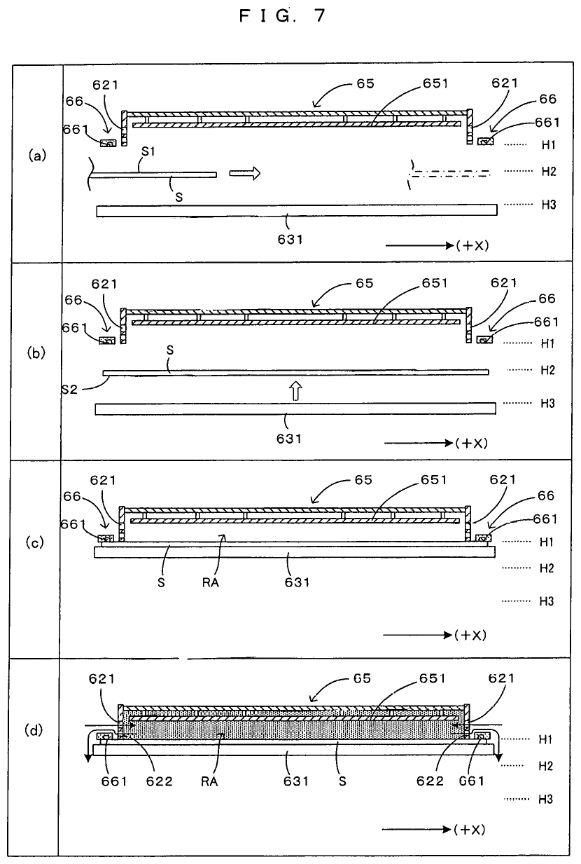

A plating device PD for performing the plating process at a plating process position (H1 in FIG. 7 described later) is provided in the plating chamber 11D located downstream of the water washing device PC in the conveying direction (+X). This plating device PD includes a roller conveying unit 61 composed of a plurality of conveyor rollers, a frame body 62 arranged at the plating process position, a lifting unit 63 for lifting the substrate S conveyed to a position below the plating process position by the roller conveying unit 61 to the plating process position to form a storage space RA (see FIG. 7) for storing a plating solution by the frame body 62 and the front surface S1 of the substrate S, and a plating solution supply unit 64 for supplying the plating solution to the storage space RA. Then, the plating process is performed using the plating solution with a back surface S2 (see FIGS. 6, 7) of the substrate S supported from below by the lifting unit 63. Further, after the plating process, the substrate S is lowered by the lifting unit 63, returned to the roller conveying unit 61 and conveyed to the second processing device row 12 by the roller conveying unit 61. The detailed configuration and operation of the plating device PD are described in detail later.

In the second processing device row 12, a transfer chamber 12A, a water washing chamber 12B and a transfer chamber 12C are provided from an upstream side in the conveying direction (+Y) of the substrate S as shown in FIG. 2B. A transfer device PE is provided in the transfer chamber 12A. This transfer device PE switches the conveying direction of the substrate S from the (+X) direction to the (+Y) direction and conveys the substrate S to the water washing chamber 12B. The configuration of the transfer device PE is described together with a transfer device PG later.

A water washing device PF having the same configuration as the water washing device PC described above is provided in the water washing chamber 12B. Specifically, the water washing device PF includes a roller conveying unit 51 composed of a plurality of conveyor rollers and a washing solution supply unit 52 for supplying water (washing solution) to the front surface S1 of the substrate S being conveyed by the roller conveying unit 51. The water stored in the washing solution tank 54 is supplied to each washing solution discharge nozzle 53 via a valve 56 by a pump 55 while the substrate S is conveyed in a horizontal posture in the (+X) direction with the front surface S1 faced up by the roller conveying unit 51, whereby the water is discharged toward the front surface S1 of the substrate S being conveyed to the transfer chamber 12C from each washing solution discharge nozzle 53 and the plating solution remaining on the substrate S is water-washed and removed.

The transfer device PG similar to the transfer device PE is provided in the transfer chamber 12C. This transfer device PG receives the substrate S subjected to the water washing process, switches the conveying direction of the substrate S from the (+Y) direction to the (−X) direction and conveys the substrate S to the third processing device row 13.

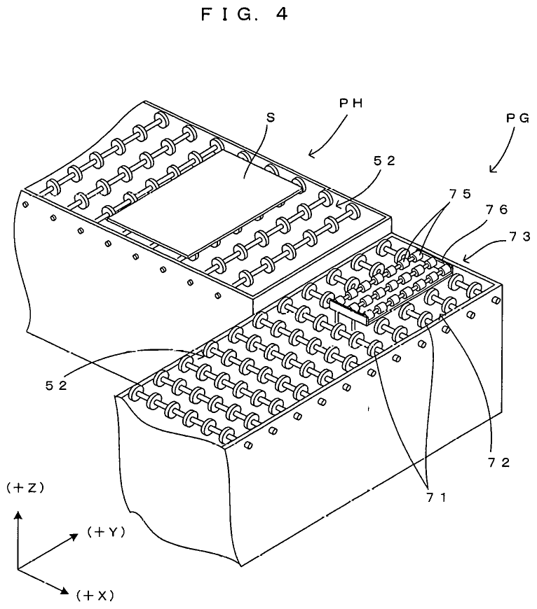

FIG. 4 is a perspective view schematically showing the configuration of the transfer device. The transfer device PG includes a Y-direction conveying unit 72 composed of a plurality of conveyor rollers 71 and configured to convey the substrate S in the (+Y) direction, an X-direction conveying unit 73 surrounded by the conveyor rollers 71 on a downstream end in the conveying direction (+Y) and configured to convey the substrate S in the (−X) direction, and an actuator 74 (FIGS. 2B, 2C, 3) such as an air cylinder for lifting and lowering the X-direction conveying unit 73. In the Y-direction conveying unit 72, as shown in FIG. 4, the conveyor rollers 71 can convey the substrate S in the (+Y) direction while supporting the substrate S from below by being rotationally driven about axes of rotation parallel to the X direction. In this embodiment, a conveyance path of the substrate S by the conveyor rollers 71 is lower than those of the substrate S in the first and third processing device rows 11 and 13.

On the other hand, in the X-direction conveying unit 73, conveyor rollers 75 are rotatably supported about axes of rotation parallel to the Y direction in a frame 76 to convey the substrate S in the (+Y) direction while supporting the substrate S from below by being rotationally driven. Further, the frame 76 is coupled to the actuator 74, and can move the X-direction conveying unit 73 to a retracted position retracted downwardly from the conveyance path of the substrate S by the conveyor rollers 71 and the same transfer position as the conveyance path of the substrate S in the third processing device row 13 in the vertical direction Z by being lifted or lowered in response to a lifting/lowering command from the control unit 20. In the transfer device PG, the substrate S is conveyed to a position facing the third processing device row 13 by the Y-direction conveying unit 72 with the X-direction conveying unit 73 positioned at the retracted position in receiving the substrate S from the water washing device PF. Subsequent to that, the actuator 74 operates to lift the X-direction conveying unit 73 to the transfer position. During this lifting movement, the substrate S is transferred from the Y-direction conveying unit 72 to the X-direction conveying unit 73. Thereafter, the substrate S is transferred to the third processing device row 13 by the conveyor rollers 75 of the X-direction conveying unit 73.

Similar to the above transfer device PG, the transfer device PE also includes a Y-direction conveying unit 72, an X-direction conveying unit 73, an actuator 74 and the like. In the transfer device PE, the X-direction conveying unit 73 is positioned at a transfer position and the substrate S is pulled into the transfer chamber 12A by the X-direction conveying unit 73 as shown in FIGS. 2A and 2B in receiving the substrate S from the plating device PD. Subsequent to that, the actuator 74 operates to lower the X-direction conveying unit 73 to a retracted position. During this lowering movement, the substrate S is transferred from the X-direction conveying unit 73 to the Y-direction conveying unit 72. Thereafter, the substrate S is conveyed to the water washing chamber 12B by the Y-direction conveying unit 72.

Next, the configuration of the third processing device row 13 is described with reference to FIG. 2C. A water washing chamber 13A; a plating chamber 1133, a water washing chamber 13C, a drying chamber 13D and an unloading chamber 13E are provided from an upstream side (side of the transfer device PG) in the conveying direction (−X) of the substrate S in the third processing device row 13. A water washing device PH having the same configuration as the water washing devices PC, PF described above is provided in the water washing chamber 13A. Specifically, the water washing device PH includes a roller conveying unit 51 composed of a plurality of conveyor rollers and a washing solution supply unit 52 for supplying water (washing solution) to the front surface S1 of the substrate S being conveyed by the roller conveying unit 51. The water stored in a washing solution tank 54 is supplied to each washing solution discharge nozzle 53 via a valve 56 by a pump 55 while the substrate S is conveyed in a horizontal posture in the (−X) direction with the front surface S1 faced up by the roller conveying unit 51, whereby the water is discharged toward the front surface S1 of the substrate S being conveyed to the plating chamber 13B from each washing solution discharge nozzle 53 and the substrate S conveyed from the second processing device row 12 is water-washed.

A plating device PJ for performing the plating process at a plating process position is provided in the plating chamber 13B located downstream of the water washing device PH in the conveying direction (−X). This plating device PJ basically has a configuration similar to that of the plating device PD except in that a membrane (electrolyte separator membrane) is provided in a frame body 62 and a plating solution supply unit 64B (see FIG. 3) for supplying another plating solution is added besides a plating solution supply unit 64A (see FIG. 3). The detailed configuration and operation of the plating device PJ are also described in detail later.

A water washing device PK having the same configuration as the water washing devices PC, PF and PH described above is provided in the water washing chamber 13C located downstream of the plating device PJ in the conveying direction (−X). Specifically, the water washing device PK includes a roller conveying unit 51 composed of a plurality of conveyor rollers and a washing solution supply unit 52 for supplying water (washing solution) to the front surface S1 of the substrate S being conveyed by the roller conveying unit 51. The water stored in a washing solution tank 54 is supplied to each washing solution discharge nozzle 53 via a valve 56 by a pump 55 while the substrate S is conveyed in a horizontal posture in the (−X) direction with the front surface S1 faced up by the roller conveying unit 51, whereby the water is discharged toward the front surface S1 of the substrate S being conveyed toward the drying chamber 13D from each washing solution discharge nozzle 53 and the plating solution remaining on substrate S is water-washed and removed.

A drying device PL for drying the substrate S subjected to a series of wet processes (pre-process, water washing process and plating process) is provided in the drying chamber 13D. This drying device PL includes a roller conveying unit 81 composed of a plurality of conveyor rollers, air knives 82, 83 arranged to respectively face the front surface S1 and the back surface S2 of the substrate S being conveyed by the roller conveying unit 81, and an air supply unit 84 (FIG. 3) for supplying high-pressure air to the air knives 82, 83. These air knives 82, 83 are for blowing high-pressure air to the front surface S1 and the back surface S of the substrate S being conveyed toward the unloading chamber 13E by the roller conveying unit 81, and the washing solution is removed to dry the substrate S by blowing high-pressure air in the drying chamber 13D.

A payout device PM for paying out the substrate S having the plating process applied thereto to the conveyor robot 14b is provided in the unloading chamber 13E. This payout device PM basically has a configuration similar to that of the receiving device PA and performs an unloading operation as follows. Specifically, the substrate S conveyed from the drying chamber 13D is received by a roller conveying unit 31 with supporting pins 33 retracted at a retracted position and moved to a payout position (position right above the retracted supporting pins 33). Then, an actuator 34 operates to lift the supporting pins 33, whereby the substrate S is pushed up from below and lifted up from the roller conveying unit 31. Subsequent to that, the conveyor robot 14b holds and returns the substrate S to the cassette C.

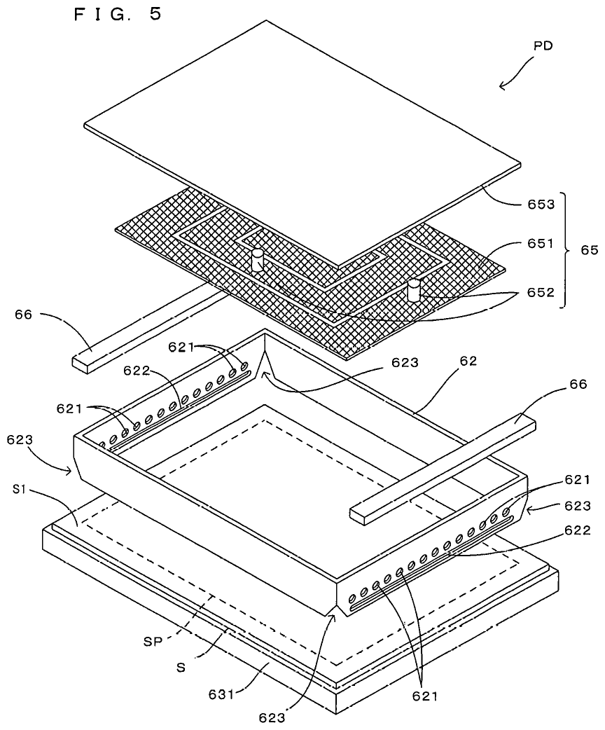

Next, the configuration of the plating device PJ is described in detail with reference to FIGS. 2C, 3, 8 and 9 after the configuration of the plating device PD is described in detail with reference to FIGS. 2A, 3 and 5 to 7. FIG. 5 is an exploded assembly perspective view schematically showing the configuration of the plating device constituting the first processing device row. Further, FIG. 6 is a diagram schematically showing lifting and lowering operations of a backup plate with respect to the conveyor rollers in the plating device of FIG. 5. Furthermore, FIG. 7 is a diagram schematically showing a plating operation by the plating device of FIG. 5.

In the plating device PD, in response to a conveyance command from the control unit 20, the roller conveying unit 61 operates to convey the substrate S in a horizontal posture with the front surface S1 of the substrate S faced up and position the substrate S right below the frame body 62. As shown in FIG. 5, the frame body 62 is finished to have a shape and a size corresponding to a region to be plated SP of the substrate S. As shown in FIG. 7, the frame body 62 is fixedly arranged above the roller conveying unit 61 such that a height position of the lower surface thereof matches a plating process position H1, and a height position H2 (FIG. 7) of the front surface S of the substrate S in the vertical direction Z when the substrate S is conveyed and positioned is lower than the plating process position H1.

Further, as shown in FIG. 5, the frame body 62 is finished to have the shape and the size corresponding to the region to be plated SP of the substrate S. The substrate S is moved in the upward direction (+Z) by the lifting unit 63, whereby a region of the front surface S1 of the substrate S surrounding the region to be plated SP comes into contact with the lower surface of the frame body 62. In this way, the storage space RA (see FIG. 7(c)) having a substantially rectangular parallelepiped shape is formed and the plating solution can be stored in the storage space RA.

In this embodiment, the lifting unit 63 is configured as follows so that a central part of the substrate S is not deflected even in a state where the substrate S is uniformly brought into contact with the frame body 62 by being lifted while being kept in the horizontal posture and the plating solution is stored in the storage space RA. Specifically, the lifting unit 63 includes a backup plate 631 functioning as a lifting member capable of moving upward and downward in the vertical direction and a lifting mechanism 632 (FIG. 3) for lifting and lowering the backup plate 631 in the vertical direction Z. The backup plate 631 has a planar size slightly larger than the substrate S as shown in column (a) of FIG. 6. In addition, a recess 634 having a special shape is provided in a plate surface 633 to lift and lower the substrate S supported from below while avoiding interference with the conveyor rollers 611 of the roller conveying unit 61. That is, the recess 634 is so shaped that the conveyor rollers 611 and a rotary shaft 612 coupling the conveyor rollers 611 to each other to rotationally drive the conveyor rollers 611 are completely fit thereinto.

When the substrate S is conveyed by the roller conveying unit 61, the lifting mechanism 632 lowers the backup plate 631 and positions the backup plate 631 at a plate lowered position so that a surface of the backup plate 631 is located at an uppermost position of the conveyor rollers 611, i.e. a position (height position H3 in FIG. 7) lower than a position where the back surface S2 of the substrate S is supported and conveyed in response to a lowering command from the control unit 20. This prevents the backup plate 631 from interfering with the substrate S during the conveyance of the substrate S. On the other hand, when the plating process is performed, the lifting mechanism 632 lifts the backup plate 631 to support the back surface S2 of the substrate S by the entire surface region of the surface 633 excluding the recess 634 and further lifts the substrate S from the conveyor rollers 611 as shown in column (b) of FIG. 6 by a further lifting movement in response to a lifting command from the control unit 20. In this way, the storage space RA can be formed by bringing the backup plate 631 into contact with the lower surface of the frame body 62.

A plurality of through holes 621 for supplying the plating solution to the storage space RA are aligned in the horizontal direction at positions distanced upward from the lower surface of the frame body 62 in some of side walls of the frame body 62. Further, slits 622 are provided between the plurality of through holes 621 and the lower surface of the frame body 62 in the side walls of the frame body 62 and notches 623 are provided at four lower corner parts of the frame body 62. These are provided to satisfactorily circulate the plating solution in the storage space RA, each through hole 621 functions as a supply location for supplying the plating solution from the plating solution supply unit 64 to the storage space RA, whereas the slits 622 and the notches 623 function as discharging parts for discharging the plating solution from the storage space RA.

As shown in FIG. 2A, the plating solution supply unit 64 includes a plating solution tank 641 for storing the plating solution, a pump 642 and a valve 643. In response to a plating process command from the control unit 20, the pump 642 operates and the valve 643 is opened to feed the plating solution stored in the plating solution tank 641 under pressure to each through hole 621 and supply the plating solution to the storage space RA via the pump 642 and the valve 643. Further, the plating solution is discharged from the storage space RA via the slits 622 and the notches 623. In this way, the plating process is possible with the plating solution stored in the storage space RA while being constantly exchanged in the storage space RA. The discharged plating solution is collected in the plating chamber 11D, returned to the plating solution tank 641 and reused.

An anode block 65, two cathode blocks 66, a cathode block lifting unit 67 (FIG. 3) and a power supply unit 68 (FIG. 3) are provided to apply electrolytic plating to the region to be plated SP of the substrate S using the plating solution stored in the storage space RA. The anode block 65 is such a structure that an anode electrode 651 having a planar size equivalent to that of the region to be plated SP is fixed in a suspended state to a supporting plate 653 by a coupling member 652 as shown in FIG. 7. The anode electrode 651 is mounted in the frame body 62 to contact the plating solution in the storage space RA while facing in parallel with the region to be plated SP.

On the other hand, each cathode block 66 is structured to prevent a cathode electrode 661 from contacting the plating solution from the frame body 62 by covering the entire cathode electrode 661 excluding the lower surface of the cathode electrode 661 by an insulating material as shown in FIG. 7. Further, each cathode block 66 is connected to a cathode block lifting unit 67 (FIG. 3). Thus, the cathode block lifting unit 67 operates in response to a lifting/lowering command from the control unit 20, whereby each cathode block 66 moves upward or downward between a power supply position (position shown in fields (c) and (d) in FIG. 7) and a retracted position (position shown in fields (a) and (b) in FIG. 7) separated upwardly from the power supply position. Here, the “power supply position” means a position where the lower surface of the cathode electrode 661 is positioned with respect to a surface peripheral edge region (surface region of the front surface S1 adjacent to the region to be plated SP) of the substrate S and electrically contacts electrodes (not shown) extending from the region to be plated SP to a surface peripheral edge part of the substrate S.

The power supply unit 68 is electrically connected to the anode electrode 651 and the cathode electrodes 661 by an unillustrated wiring. In a state where the anode electrode 651 is in contact with the plating solution in the storage space RA and the cathode blocks 66 are positioned at the power supply position, the power supply unit 68 causes a current to flow between the anode electrode 651 and the cathode electrodes 661 in response to a power supply command from the control unit 20, whereby the plating process can be performed,

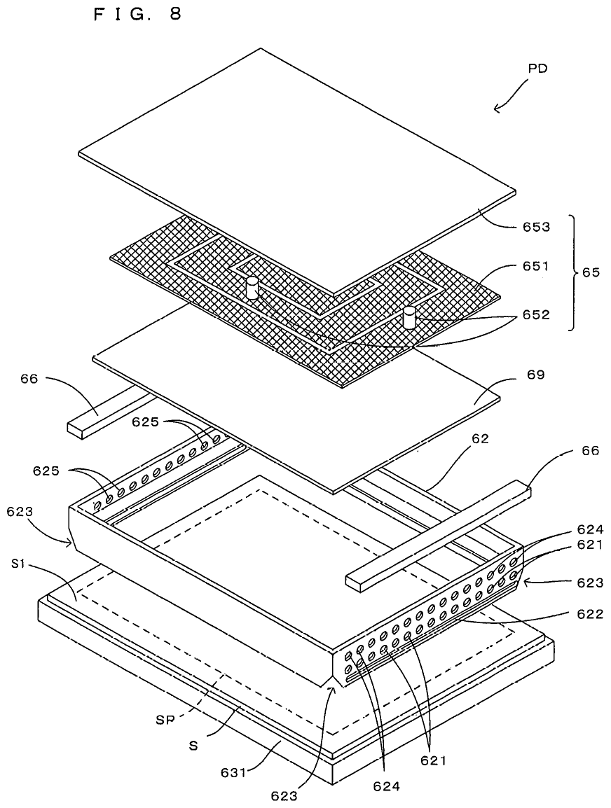

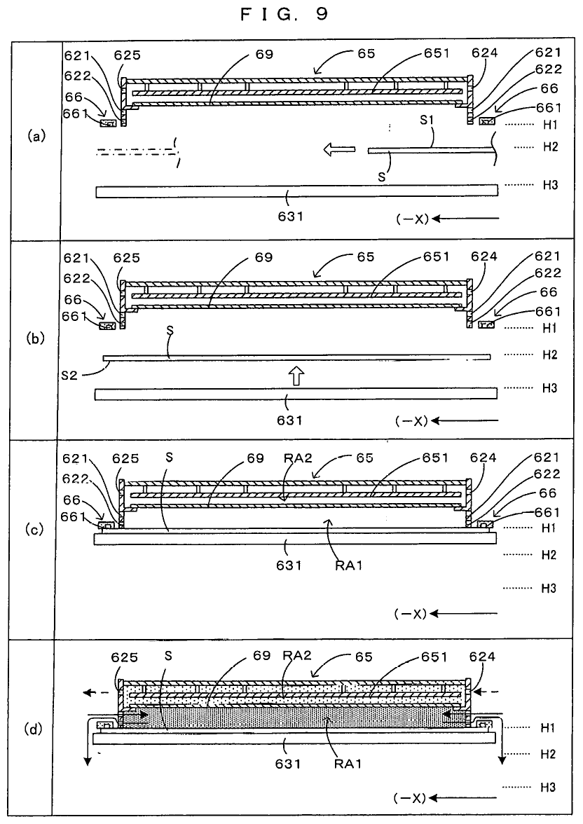

FIG. 8 is an exploded assembly perspective view schematically showing the configuration of the plating device constituting the third processing device row. Further, FIG. 9 is a diagram schematically showing a plating operation by the plating device of FIG. 8.

In the plating device PJ, a membrane 69 is provided below an anode block 65 inside a frame body 62, whereby the inside of the frame body 62 is divided into an upper region and a lower region as shown in fields (c) and (d) of FIG. 9. Similar to the plating device PD, through holes 621, slits 622 and notches 623 are provided in parts of side walls of the frame body 62 corresponding to the upper and lower regions. Further, a first plating solution supply unit 64A having the same configuration as the plating solution supply unit 64 of the plating device PD is connected to the through holes 621, a first plating solution supplied from the first plating solution supply unit 64A can be stored in a first storage space RA1 sandwiched by the region to be plated SP of the substrate S and the membrane 69.

On the other hand, in parts of the side walls of the frame body 62 corresponding to the upper region, a plurality of through holes 624 are aligned in a horizontal direction in one side wall and a plurality of through holes 625 are aligned in a horizontal direction in another side wall facing the one side wall. These through holes 624, 625 are connected to a second plating solution supply unit 64B.

As shown in FIG. 2C, the second plating solution supply unit 64B includes a plating solution tank 644 for storing a second plating solution, a pump 645 and a valve 646. In response to a plating process command from the control unit 20, the pump 645 operates and the valve 646 is opened to feed the second plating solution stored in the plating solution tank 644 under pressure to each through hole 624 and supply the second plating solution to a second storage space RA2 sandwiched by the anode block 65 and the membrane 69 via the pump 645 and the valve 646. Further, each through hole 625 is connected to the plating solution tank 644, and the second plating solution discharged from each through hole 625 is returned to the plating solution tank 644 and reused. As just described, the plating process is performed without the second plating solution being discharged to the plating chamber 13B for the plating process and without mixing the first plating solution and the second plating solution. Since the other components are the same as those of the plating device PD, the same components are denoted by the same reference signs and not described.

In the substrate processing system 1 configured as described above, the control unit 20 includes a CPU (Central Processing Unit) 21, a memory 22 and the like as shown in FIG. 3. The CPU 21 executes a control program prepared in advance to perform a series of processes including the plating processes while conveying and stopping the conveyance of the substrate S in each processing device PA to PH, PJ to PM and controlling a conveying speed by controlling each system component. The processes performed in the substrate processing system 1 are described below, focusing on one substrate S.

The substrate S to be plated is taken out from the substrate storage cassette C by the conveyor robot 14b and conveyed to the receiving device PA of the first processing device row 11 (loading process). Then, the substrate S is conveyed to the pre-processing device PB by the receiving device PA and has organic components and oxide components removed from the substrate S by the chemical (pre-process). Subsequent to that, the substrate S is conveyed from the pre-processing device PB to the water washing device PC and then conveyed to the plating device PD after being water-washed in the water washing device PC.

In the plating device PD, the substrate S is plated in a stationary state at the plating process position as described in detail next and the substrate S is not conveyed by the roller conveying unit 61 during that time. That is, the water washing device PC needs to convey the substrate S at a timing at which the substrate S can be received in the plating device PD. In addition, the above timing differs depending on a plating process time (process time). Accordingly, in this embodiment, a timing at which the substrate S is conveyed from the water washing device PC is determined by the CPU 21 of the control unit 20 on the basis of the time of the plating process performed on the substrate S in the plating device PD before the conveyance of the substrate S, and the roller conveying unit 51 of the water washing device PC is controlled according to the determined timing. Specifically, the above timing is controlled by switching the conveyance and the conveyance stop of the substrate S or reciprocally moving the substrate S in the water washing device PC. Further, in the case of changing the timing, a residence time of the substrate S in the water washing device PC changes. In this embodiment, an amount of the washing solution discharged from the washing solution discharge nozzles 53 per unit time is controlled according to the residence time. Thus, the substrate S is conveyed to the plating device PD after the water washing process is properly performed.

As just described, in this embodiment, the plating device PD and the roller conveying unit 61 provided in the plating device PD respectively correspond to examples of a “plating device” and a “first conveying unit” of the invention, and the substrate S plated by this plating device PD corresponds to a “first substrate” of the invention. On the other hand, the water washing device PC located upstream of, i.e. in a previous stage of the plating device PD in the conveying direction (+X) of the substrate S and the roller conveying unit 51 provided in the water washing device PC respectively correspond to examples of a “pre-stage device” and a “second conveying unit” of the invention, the substrate S conveyed from the water washing device PC to the plating device PD corresponds to a “second substrate” of the invention, and the washing solution and the washing solution supply unit 52 respectively correspond to examples of a “processing solution” and a “processing solution supply unit” of the invention.

When the substrate S is conveyed from the water washing device PC to the plating chamber 11D at the above timing, each device component operates to perform the plating process in the plating device PD as shown in FIG. 7. First, the roller conveying unit 61 operates to convey the substrate S conveyed from the water washing device PC in the conveying direction (+X) (field (a) in FIG. 7). At this time, the plating solution and power are not supplied and the backup plate 631 is positioned at the plate lowered position (height position H3) to avoid interference with the substrate S. When the substrate S moves to a position right below the plating process position, the conveyance of the substrate S by the roller conveying unit 61 is stopped and the substrate S is positioned. Subsequent to that, the backup plate 631 is lifted by the lifting mechanism 632 (field (b) in FIG. 7). In this way, the substrate S is lifted up from the conveyor rollers 611 with the back surface S2 of the substrate S supported by the entire surface 633 of the backup plate 631 and further comes into contact with the lower surface of the frame body 62 to form the storage space RA (field (c) in FIG. 7). Further, each cathode block 66 is lowered to the power supply position by the cathode block lifting unit 67, thereby completing the preparation of power supply to the region to be plated SP via the cathode electrodes 661.

Subsequently, the pump 642 operates and the valve 643 is opened to supply the plating solution in the plating solution tank 641 from each through hole 621 to the storage space RA. Although the plating solution is discharged via the slits 622 and the notches 623 in this storage space RA, the plating solution is continuously supplied during the plating process, and a space between the anode electrode 651 and the region to be plated SP is filled with the plating solution and the plating solution is flowing during the plating process. Further, since the entire back surface S2 of the substrate S is supported from below by the backup plate 631, an interval between the anode electrode 651 and the region to be plated SP in the vertical direction Z is substantially uniform within the plane of the region to be plated SP. The power supply unit 68 causes a current to flow between the anode electrode 651 and the cathode electrodes 661 with such a state suitable for the plating process maintained, thereby performing the plating process (field (d) in FIG. 7). As a result, a desired plating layer is formed in the region to be plated SP.

When the plating solution is completed, the backup plate 631 is lowered to the plate lowered position (height position H3) after power supply by the power supply unit 68 is stopped and the supply of the plating solution by the plating solution supply unit 64 is stopped. During this lowering movement, the substrate S subjected to the plating process is transferred to the conveyor rollers 611 of the roller conveying unit 61. Subsequent to that, the substrate S is conveyed to the transfer chamber 12A of the second processing device row 12 by the roller conveying unit 61.

In this transfer chamber 12A, the conveying direction of the substrate S is converted from the (+X) direction to the (+Y) direction by the transfer device PE and the substrate S is conveyed to the water washing chamber 12B. After the plating solution remaining on the substrate S is water-washed by the water washing device PF in the water washing chamber 121B the substrate is conveyed to the transfer chamber 12C. In this transfer chamber 12C, the conveying direction of the substrate S is further converted from the (+Y) direction to the (−X) direction by the transfer device PG and the substrate S is conveyed to the third processing device row 13.

In the third processing device row 13, the substrate S is conveyed to the plating device PJ after being water-washed in the water washing device PH. Here, in the plating device PJ, the substrate S is plated in a stationary state at the plating process position as in the plating device PD. Thus, a timing at which the substrate S is conveyed from the water washing device PH to the plating device PJ needs to be properly set. Accordingly, in this embodiment, the CPU 21 of the control unit 20 calculates the timing and the roller conveying unit 51 of the water washing device PH is controlled according to the calculated timing. As just described, in this embodiment, the plating device PJ and the roller conveying unit 61 provided in the plating device PJ respectively correspond to examples of the “plating device” and the “first conveying unit” of the invention also in the third processing device row 13 as in the first processing device row 1, and the substrate S plated by this plating device PJ corresponds to the “first substrate” of the invention. On the other hand, the water washing device PH located upstream of, i.e. in a previous stage of the plating device PJ in the conveying direction (+X) of the substrate S and the roller conveying unit 51 provided in the water washing device PH respectively correspond to examples of the “pre-stage device” and the “second conveying unit” of the invention, and the substrate S conveyed from the water washing device PH to the plating device PJ corresponds to the “second substrate” of the invention.

When the substrate S is conveyed from the water washing device PH to the plating chamber 13B at the above timing, each device component operates to perform the plating process in the plating device PJ as shown in FIG. 9. Specifically, the plating process is basically performed similarly to the plating device PD of the first processing device row 11 except that the first plating solution and the second plating solution are used. Specifically, the substrate S is conveyed in the conveying direction (−X) by the roller conveying unit 61 with the backup plate 631 positioned at the plate lowered portion (height position H3) (field (a) in FIG. 9). When the substrate S moves to a position right below the plating process position, the backup plate 631 is lifted by the lifting mechanism 632 (field (b) in FIG. 9) after the conveyance of the substrate S by the roller conveying unit 61 is stopped. In this way, the substrate S is lifted up from the conveyor rollers 611 with the back surface S2 of the substrate S supported by the entire surface 633 of the backup plate 631 and further comes into contact with the lower surface of the frame body 62 to form the storage space RA1 (field (c) in FIG. 9). Further, each cathode block 66 is lowered to the power supply position by the cathode block lifting unit 67, thereby completing the preparation of power supply to the region to be plated SP via the cathode electrodes 661.

Subsequently, in the first plating solution supply unit 64A, the pump 642 operates and the valve 643 is opened to supply the plating solution in the first plating solution tank 641 from each through hole 621 to the storage space RA1, and a space between the membrane 69 and the region to be plated SP is filled with the flowing plating solution as in the plating device PD in the first processing device row 11. Further, also in the second plating solution supply unit 64B, the pump 642 operates and the valve 643 is opened to supply the plating solution in the second plating solution tank 644 from each through hole 624 to the storage space RA2, and the second plating solution discharged from the storage space RA1 via each through hole 625 is returned to the second plating solution tank 644. Thus, the second plating solution is filled in the second storage space RA2 while flowing between the anode block 65 and the membrane 69. Although the membrane 69 is arranged between the anode electrode 651 and the region to be plated SP in this plating device PJ, an interval between the anode electrode 651 and the region to be plated SP in the vertical direction Z is substantially uniform within the plane of the region to be plated SP. The power supply unit 68 causes a current to flow between the anode electrode 651 and the cathode electrodes 661 with such a state suitable for the plating process maintained, thereby performing the plating process (field (d) in FIG. 9). As a result, a desired plating layer is formed in the region to be plated SP.

When the plating solution is completed, the backup plate 631 is lowered to the plate lowered position (height position H3) after power supply by the power supply unit 68 is stopped and the supply of the plating solution by the plating solution supply unit 64 is stopped. During this lowering movement, the substrate S subjected to the plating process is transferred to the conveyor rollers 611 of the roller conveying unit 61. Subsequent to that, the substrate S is conveyed to the water washing chamber 13C by the roller conveying unit 61.

In this water washing chamber 13C, the substrate S is conveyed to the drying chamber 13D, dried through the drying process by the drying device PL and conveyed to the unloading chamber 13E after the plating solution remaining on the substrate S is water-washed and removed by the water washing device PK. Then, in the unloading chamber 13E, the substrate S subjected to the series of processes including the plating processes is transferred to the conveyor robot 14b by the payout device PM and returned to the cassette C by this conveyor robot 14b.

In the embodiment configured as described above, the following functions and effects are achieved.

(1) When the plating process for the substrate S in the plating device PD (PJ) is completed, the substrate S is conveyed to the next processing device PE (PK), whereas the substrate S subjected to the water washing process is conveyed to the plating device PD (PJ) to be plated. In this way, the plating process is continuously performed and throughput can be improved. Further, even if the plating process time is changed, the timing at which the substrate S is conveyed to the plating device PD (PJ) is controlled according to that change in the water washing device PC (PH) in the previous stage. Thus, the plating process can be performed by conveying the substrate S to the plating device PD (PJ) properly and without interruption. In this way, a change in the plating process time can be flexibly coped with and high versatility is obtained.

(2) Since the above timing is controlled by switching the conveyance and the conveyance stop of the substrate S or reciprocally moving the substrate S in the water washing device PC, PH, the above timing can be controlled with high accuracy and the substrate S can be properly conveyed to the plating device PD, PJ.

(3) The water washing device PC, PH performs the water washing process by discharging the washing solution from the washing solution discharge nozzles 53 while conveying the substrate S by the roller conveying unit 51. The amount of the washing solution discharged from the washing solution discharge nozzles 53 per unit time can be controlled. Thus, the water washing process can be properly performed. Particularly, in the case of changing the timing at which the substrate S is conveyed to the plating device PD, PJ, the residence time of the substrate S in the water washing device PC, PH changes, but the water washing process can be made proper by supplying the amount of the washing solution corresponding to the changed time to the substrate S.

(4) The plurality of conveyor rollers 611 constituting the roller conveying unit 61 convey the substrate S to the position below the frame body 62 (position vertically below the plating process position) while supporting the back surface S2 of the substrate S, i.e. the principal surface opposite to the region to be plated SP. Thus, the substrate S can be stably conveyed to the position where the plating process is performed regardless of the size of the substrate S. Further, the backup plate 631 is lifted by the lifting mechanism 632 to lift up the substrate S from the conveyor rollers 611 while supporting the back surface S2 of the substrate S from below, and brought into contact with the lower surface of the frame body 62 to form the storage space RA. Since the plating process is performed using the plating solution stored in this storage space RA, a load of the plating solution is applied to the region to be plated SP of the substrate S. However, since the substrate S is supported from below by the backup plate 631 of the lifting unit 63, the deflection of the substrate S can be suppressed and the plating process can be satisfactorily performed on the region to be plated SP in the plating device PD. These function and effect also apply to the plating device PJ.

(5) The plating solution is discharged from the storage space RA via the slits 622 and the notches 623 and supplied to the storage space RA, RA1 via the through holes 621 from the plating solution supply unit 64. Thus, fresh plating solution can be efficiently supplied into the storage space RA and the plating process can be stably and satisfactorily performed with high quality in the plating device PD. These function and effect also apply to the plating device PJ.

The invention is not limited to the above embodiment and various changes other than those described above can be made without departing from the gist of the invention. For example, although the substrate S is conveyed and stopped being conveyed or reciprocally moved without changing the conveying speed thereof by the roller conveying unit 51 to control the above timing in the first embodiment, a control may be executed to change the conveying speed. Further, the amount of the washing solution discharged from the washing solution discharge nozzles 53 per unit time may be controlled according to a change in the conveying speed.

Further, although the conveying time of the substrate S from the water washing device PC (PH) located in the previous stage of the plating device PD (PJ) is controlled according to the plating process time in the plating device PD (PJ) in the above first embodiment, the conveyance timing control is not limited to this. For example, a conveyance timing of the substrate S from the pre-processing device PB (transfer device PG) in a previous stage of the water washing device PC (PH) (in a second previous stage when viewed from the plating device PD (PJ)) may be controlled in place of or together with the above timing control. A stable substrate process can be performed in each processing device by distributing the conveyance timing control among a plurality of processing devices in this way. In this case, the pre-processing device PB and the roller conveying unit 41 provided in the pre-processing device PB respectively correspond to examples of a “second previous-stage device” and a “third conveying unit” of the invention. Further, the transfer device PG corresponds to an example of the “second previous-stage device” of the invention and the Y-direction conveying unit 72 and the X-direction conveying unit 73 provided in the transfer device PG correspond to examples of the “third conveying unit” of the invention.

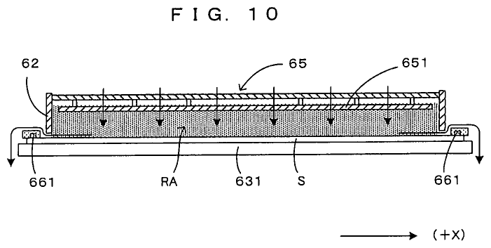

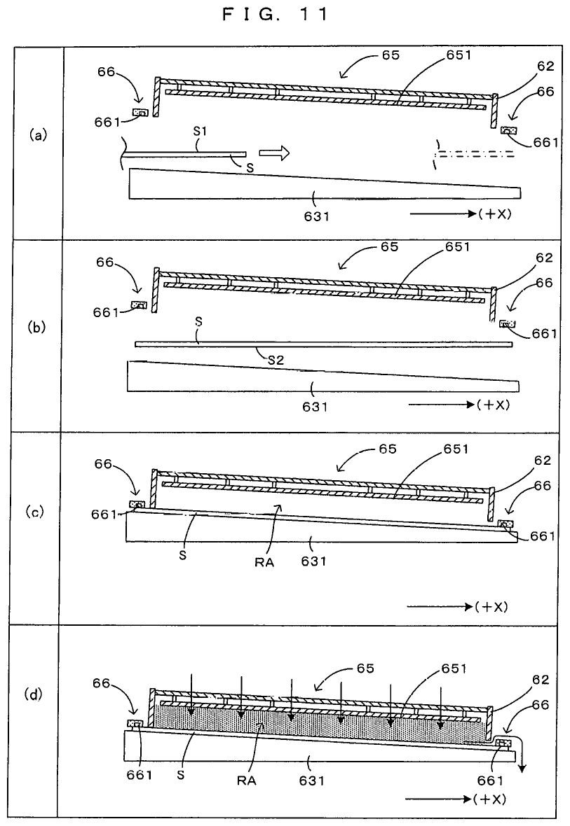

Further, although the through holes 621 for supplying the plating solution are provided in the side walls of the frame body 62 in the above first embodiment, a supply path of the plating solution is arbitrary without being limited to this. Further, the through holes 622 and the notches 623 are provided in the side walls of the frame body 62 for discharge from the storage space RA, but a plating solution discharge path is also arbitrary without being limited to this. For example, as shown in FIG. 10, the plating solution may be supplied to the storage space RA via the anode block 65 with the front surface S1 of the substrate S positioned below and at a distance from the lower surface of the frame body 62 (second embodiment). In this second embodiment, the plating solution is supplied to the storage space RA from above the storage space RA and the plating solution in the storage space RA is discharged from a clearance formed between the lower surface of the frame body 62 and the region to be plated SP. Since the plating solution is isotropically discharged from the substrate S within a horizontal plane in the second embodiment, the plating solution is less likely to stay in the storage space RA and the plating process can be more satisfactorily performed. Further, a discharge speed after the plating solution is also high and a processing time in the plating device PD can be shortened.

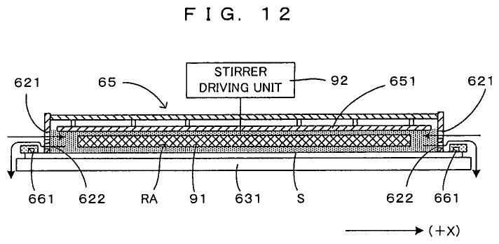

Further, although each plating device PD, PJ forms the storage space RA, RA1 between the region to be plated SP and the frame body 62 by lifting the substrate S conveyed in the horizontal posture as it is in the above embodiment, the plating process may be performed with the posture of the substrate S converted into an inclined posture as shown in FIG. 11 (third embodiment). In this third embodiment, as shown in FIG. 11, a surface 631a of a backup plate 631 is inclined by several degrees with respect to a horizontal plane. Further, in response to this, a frame body 62, an anode block 65 and each cathode block 66 are also inclined by the same angle. Since other components are basically the same as those of the above first embodiment, the same components are denoted by the same reference signs and not described.

In this third embodiment, when a substrate S is conveyed in a horizontal posture by a roller conveying unit 61 as shown in field (a) in FIG. 11, a plating process is performed as follows. When the substrate S moves to a position vertically below the frame body 62, the conveyance of the substrate S by the roller conveying unit 61 is stopped and the substrate S is positioned. Subsequent to that, the backup plate 631 is lifted by a lifting mechanism 632 (field (b) in FIG. 11). In this way, the substrate S is lifted up from conveyor rollers 611 while a back surface S2 of the substrate S is supported by an entire surface 633 of the backup plate 631 and the substrate S is inclined by several degrees with respect to the horizontal plane, and further comes into contact with the lower surface of the frame body 62 similarly inclined by several degrees to form a storage space RA (field (c) in FIG. 11). Subsequent to that, as in the first embodiment, a plating solution in a plating solution tank 641 is continuously supplied to the storage space RA after each cathode block 66 is lowered to a power supply position. Here, since the substrate S is inclined in the third embodiment, the plating solution supplied to the storage space RA flows in a direction of inclination (lower right direction in FIG. 11) along a region to be plated SP and is discharged from the storage space RA as shown in field (d) in FIG. 11. Thus, the plating solution does not stay in the storage space RA and, in addition, the plating solution is continuously supplied to the region to be plated SP to promote a plating reaction in the region to be plated SP. Therefore, the plating process can be more satisfactorily performed.

When the plating process is completed, power supply by the power supply unit 68 is stopped and the supply of the plating solution by the plating solution supply unit 64 is stopped, but the plating solution can be discharged from the storage space RA in a short time after the stop of the supply. Thus, a tack time in the plating device PD can be shortened. Although an inclined structure is adopted for the plating device PD here, the above inclined structure may be adopted for the plating device PJ and similar functions and effects are obtained.

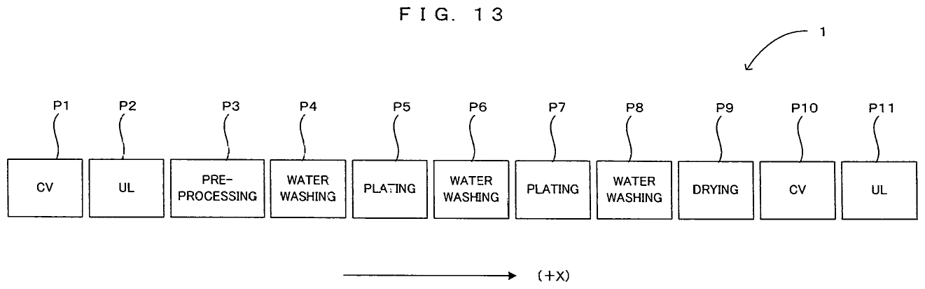

Further, it is desirable to promote the plating reaction in the region to be plated SP as described above in order to improve the plating process. For example, as shown in FIG. 12, a stirrer 91 may be arranged in a storage space RA and operated by a stirrer driving unit 92 to stir a plating solution near a region to be plated SP (fourth embodiment). It goes without saying that such a stirrer 91 is also applicable to the plating device PJ.

Further, although the storage space RA, RA1 is formed by moving the substrate S toward the frame body 62 while supporting the substrate S from below by the backup plate 631 in the above embodiment, the storage space RA, RA1 may be formed by lowering the frame body 62. In this case, the back surface S2 of the substrate S may be supported only by the conveyor rollers 611, but the substrate S is preferably supported by the backup plate 631 and the conveyor rollers 611 by lifting the surface 633 of the backup plate 631 up to a position where the surface 633 comes into contact with the back surface S2 of the substrate S. Further, the storage space RA, RA1 may also be formed by moving both the frame body 62 and the backup plate 631. In short, the storage space RA, RA1 for storing the plating solution only has to be formed by the frame body 62 and the region to be plated SP by relatively lifting the substrate S with respect to the frame body 62, and the substrate S may be supported from below by at least either the backup plate 631 or the conveyor rollers 611.

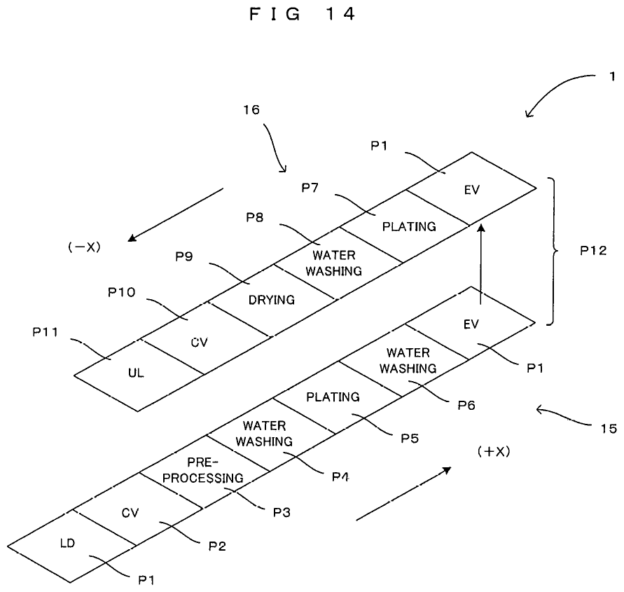

Further, in the substrate processing system 1 shown in FIG. 1, the indexer device 14 and the plurality of processing devices PA to PH, PJ to PM are coupled into a U shape in a plan view, but an alignment structure of the processing devices, the number of the processing devices and the like are arbitrary. For example, as shown in FIG. 13, a conveyor robot P1 for performing a loading process, a receiving device P2 for receiving a substrate from the conveyor robot, a pre-processing device P3 for performing a pre-process, a water washing device P4 for performing a water washing process, a plating device P5 for performing a plating process, a water washing device P6 for performing a water washing process, a plating device P7 for performing a plating process, a water washing device P8 for performing a water washing process, a drying device P9 for performing a drying process, a payout device P10 for paying out the substrate, and a conveyor robot P11 for performing an unloading process of the paid-out substrate may be linearly arranged. Further, as shown in FIG. 14, a processing device row 15 in which processing devices P1 to P6 are aligned and a processing device row 16 in which processing devices P7 to P11 are aligned may be stacked and arranged, and an elevator device P12 for conveying a substrate from the processing device P6 to the processing device P7 may be provided. By adopting such a stacking structure, the footprint of the substrate processing system 1 can be reduced.

Further, although the conveyance timing of the substrate S to the plating device PD, PJ is controlled according to the plating process time in the plating device PD, PJ in the above embodiment, the conveyance timing may be controlled as follows. If it is not possible to perform the washing process with the conveying speed of the substrate S by the roller conveying unit 51 kept constant and convey the substrate S to the plating device PD, PJ when the washing process is completed, the conveyance timing may be adjusted by waiting in the water washing device. Further, the substrate S may be conveyed to the plating device PD, PJ without being stopped by changing the conveying speed of the substrate S in the water washing device according to the plating process time, whereas a supply amount of the washing solution per unit time may be changed in response to that speed change. For example, if the plating process takes a relatively long time, the supply amount of the washing solution per unit time may be reduced while the substrate S is conveyed slowly in the water washing device.

Although the invention has been described by way of the specific embodiment above, this description is not intended to be interpreted in a limited sense. Similar to other embodiments of the invention, various modifications of the disclosed embodiment will become more apparent to a person skilled in this art by referring to the description of the invention. Therefore, appended claims are construed to include these modifications or embodiments without departing from the true scope of the invention.

### INDUSTRIAL APPLICABILITY

The invention is generally applicable to a substrate processing system and a substrate processing method for applying a plating process to surfaces of substrates.

### REFERENCE SIGNS LIST

41 roller conveying unit (third conveying unit)
51 roller conveying unit (second conveying unit)
52 washing solution supply unit (processing solution supply unit)
53 washing solution discharge nozzle
61 roller conveying unit (first conveying unit)
62 frame body
63 lifting unit
64,64A plating solution supply unit
68 power supply unit
72 y-direction conveying unit (third conveying unit)
73 x-direction conveying unit (third conveying unit)
622 slit (discharging part)
623 notch (discharging part)
631 backup plate (lifting member)
632 lifting mechanism
651 anode electrode
661 cathode electrodes
PB pre-processing device (second previous-stage device)
PC, PH water washing device (pre-stage device)
PG transfer device (second previous-stage device)
RA, RA1 storage space
S substrate
S1 front surface of substrate (one principal surface)
S2 back surface of substrate (other principal surface)
SP region to be plated

1. A substrate processing system, comprising:
a plating device including a first conveying unit for conveying a first substrate and configured to convey the first substrate by the first conveying unit after a plating process is applied to a surface of the first substrate in a stationary state; and
a pre-stage device including a second conveying unit for conveying a second substrate and configured to convey the second substrate as the first substrate to the plating device by the second conveying unit in response to unloading of the first substrate by the first conveying unit, wherein
a timing at which the second conveying unit conveys the second substrate to the plating device being controlled according to a plating process time.

2. The substrate processing system according to claim 1, wherein:
the timing is controlled by switching the conveyance and the conveyance stop of the second substrate in the pre-stage device.

3. The substrate processing system according to claim 1, wherein:
the second conveying unit is capable of reciprocally moving the second substrate in a conveying direction toward the plating device; and
the timing is controlled by reciprocally moving the second substrate in the pre-stage device.

4. The substrate processing system according to claim 2, wherein:
the pre-stage device includes a nozzle for discharging a processing solution to the second substrate being conveyed by the second conveying unit and a processing solution supply unit for supplying the processing solution to the nozzle; and
an amount of the processing solution discharged from the nozzle per unit time is controllable.

5. The substrate processing system according to claim 1, further comprising:
a second previous-stage device including a third conveying unit for conveying the second substrate to the pre-stage device, wherein:
a timing at which the third conveying unit conveys the second substrate to the pre-stage device is controlled according to the plating process time.

6. The substrate processing system according to claim 1, wherein:
the plating device includes:
a frame body shaped to surround a region to be plated on one principal surface of the first substrate;
a lifting unit for relatively lifting the substrate with respect to the frame body to form a storage space for storing a plating solution by the frame body and the region to be plated;
a supply unit for supplying the plating solution to the storage space;
a cathode electrode electrically connected to the region to be plated; and
an anode electrode to be held in contact with the plating solution stored in the storage space;
the first conveying unit conveys the substrate to a position below the frame body while supporting the other principle surface of the substrate with the region to be plated faced up; and
the plating process is performed by causing a current to flow between the cathode electrode and the anode electrode while the other principle surface of the substrate is supported from below by at least one of the lifting unit and the first conveying unit.

7. A substrate processing method, comprising:
unloading a first substrate from a plating device after a plating process is applied to a surface of the first substrate in a stationary state by the plating device; and
conveying a second substrate as the first substrate to the plating device by a pre-stage device, wherein
a timing at which the second substrate is conveyed to the plating device being controlled according to a plating process time.
